(19) United States
(12) Patent Application Publication
(10) Pub. No.: US 2026/0156804 A1
(43) Pub. Date: Jun. 4, 2026

(54) MEMORY DEVICE

(71) Applicant: SK hynix Inc., Gyeonggi-do (KR)

(72) Inventor: Heon Yong CHANG, Gyeonggi-do (KR)

(21) Appl. No.: 19/098,942

(22) Filed: Apr. 2, 2025

(30) Foreign Application Priority Data
Dec. 4, 2024 (KR) 10-2024-0178105

(51) Int. Cl. H10B 12/00; H01L 23/00

(52) U.S. Cl. CPC H10B 12/315; H10B 12/482; H10B 12/485; H10W 72/926; H10W 72/936; H10W 80/721; H10W 80/732

(57) ABSTRACT

A memory device according to embodiments of the present disclosure comprises a first semiconductor structure, a second semiconductor structure on the first semiconductor structure, a first bonding insulation layer between the first semiconductor structure and the second semiconductor structure, a second bonding insulation layer between the first bonding insulation layer and the second semiconductor structure, a pad structure connected to the first semiconductor structure through the first bonding insulation layer, and a contact plug connected to the pad structure, extending in a direction perpendicular to an upper surface of the pad structure to be connected to the second semiconductor structure, and having a width less than a width of the upper surface of the pad structure.

### CROSS-REFERENCES TO RELATED APPLICATION

The present application claims priority under 35 U.S.C. 119(a) to Korean patent application number 10-2024-0178105 filed on Dec. 4, 2024, which is incorporated herein by reference in its entirety.

### TECHNICAL FIELD

Embodiments of the present disclosure relate generally to a memory device.

### BACKGROUND

By their miniaturization, multi-functionality, and/or low manufacturing cost characteristics, memory devices are attracting attention as an important element in the electronics industry. As the electronics industry advances, memory devices are becoming increasingly highly integrated. For highly integrated memory devices, the width of the lines included in the memory device is gradually decreasing, increasing the difficulty in forming the memory device.

For high integration of the memory device, a process is used in which the wafer where memory cells are arranged, and the wafer where peripheral circuits are arranged are separately produced and then bonded together. When the memory device is manufactured by bonding the wafers, it is required to form various lines and contacts for electrical connection between the memory cell and the peripheral circuit.

### SUMMARY

Embodiments of the present disclosure provide a memory device capable of preventing defects in electrical connection between memory cell and peripheral circuit.

Embodiments of the present disclosure are not limited to those set forth herein, and other unmentioned embodiments would be apparent to one of ordinary skill in the art from the following description.

Embodiments of the present disclosure provide a memory device comprising a first semiconductor structure, a second semiconductor structure disposed on the first semiconductor structure, a first bonding insulation layer disposed between the first semiconductor structure and the second semiconductor structure, a second bonding insulation layer disposed between the first bonding insulation layer and the second semiconductor structure, a pad structure connected to the first semiconductor structure through the first bonding insulation layer, and a contact plug connected to the pad structure, extending in a direction perpendicular to an upper surface of the pad structure to be connected to the second semiconductor structure, and having a width less than a width of the upper surface of the pad structure.

Embodiments of the present disclosure provide a memory device comprising a substrate including a cell area and a peripheral area, a bonding insulation layer on the substrate, a pad structure disposed in the peripheral area and extending to an inside of the bonding insulation layer, and a contact plug connected to the pad structure, extending in a direction perpendicular to an upper surface of the pad structure, and having a width less than a width of the upper surface of the pad structure.

Embodiments of the present disclosure provide a memory device comprising a first semiconductor structure, and a second semiconductor structure bonded together with the first semiconductor structure via a bonding structure, a pad structure connected to the first semiconductor structure through the bonding structure, and a contact plug connected to the pad structure, the contact plug extending in a direction perpendicular to an upper surface of the pad structure to connect to the bonding structure.

According to embodiments of the present disclosure, it is possible to prevent defects in electrical connections between a memory cell and a peripheral circuit.

The advantageous effects of the embodiments of the present disclosure are not limited to the foregoing embodiments, and other advantages will be apparent to one of ordinary skill in the art from the following detailed description.

### BRIEF DESCRIPTION OF THE DRAWINGS

The embodiments of the present disclosure will be more fully understood from the following detailed description and the accompanying drawings, which are provided for illustration only and are not intended to limit the embodiments.

FIG. 1 is a view illustrating a cross-sectional structure of a memory device according to an embodiment of the present disclosure;

FIG. 2 is a view illustrating another cross-sectional structure of a memory device according to an embodiment of the present disclosure;

FIGS. 3 to 13 are views illustrating a method for manufacturing a memory device according to embodiments of the present disclosure; and

FIGS. 14 to 16 are views illustrating another method for manufacturing a memory device according to embodiments of the present disclosure.

### DETAILED DESCRIPTION

Hereinafter, embodiments of the present disclosure are described in detail with reference to the accompanying drawings. In assigning reference numerals to components of each drawing, the same components may be assigned the same numerals even when they are shown on different drawings. When determined to make the subject matter of the present disclosure unclear, the details of the known art or functions may be skipped. As used herein, when a component “includes,” “has,” or “is composed of” another component, the component may add other components unless the component “only” includes, has, or is composed of” the other component. As used herein, the singular forms “a”, “an” and “the” are intended to include the plural forms as well, unless the context clearly indicates otherwise.

Labels as “first,” “second,” “A,” “B,” “(a),” and “(b),” may be used in describing the components of the embodiments. These labels are provided merely to distinguish a component from another, and the essence, order, or number of the components are not limited by the denotations.

In describing the positional relationship between components, when two or more components are described as “connected”, “coupled” or “linked”, the two or more components may be directly “connected”, “coupled” or “linked” “, or another component may intervene. Here, the other component may be included in one or more of the two or more components that are “connected”, “coupled” or “linked” to each other.

When such terms as, e.g., “after”, “next to”, “after”, and “before”, are used to describe the temporal flow relationship related to components, operation methods, and fabricating methods, it may include a non-continuous relationship unless the term “immediately” or “directly” is used.

When a component is designated with a value or its corresponding information (e.g., level), the value or the corresponding information may be interpreted as including a tolerance that may arise due to various factors (e.g., process factors, internal or external impacts, or noise).

Hereinafter, various embodiments of the present disclosure will be described in detail with reference to the accompanying drawings.

In the accompanying drawings, the two directions parallel to the upper surface of the substrate are defined as a first direction FD and a second direction SD, respectively, and the direction protruding vertically from the upper surface of the substrate is defined as a third direction VD. The first direction FD and the second direction SD may be substantially perpendicular to each other. The third direction VD is a direction perpendicular to the first direction FD and the second direction SD. In the following specification, ‘vertical’ or ‘vertical direction’ will be used as substantially having the same meaning as the third direction VD. The direction indicated by arrow in the drawings and the opposite direction indicate the same direction.

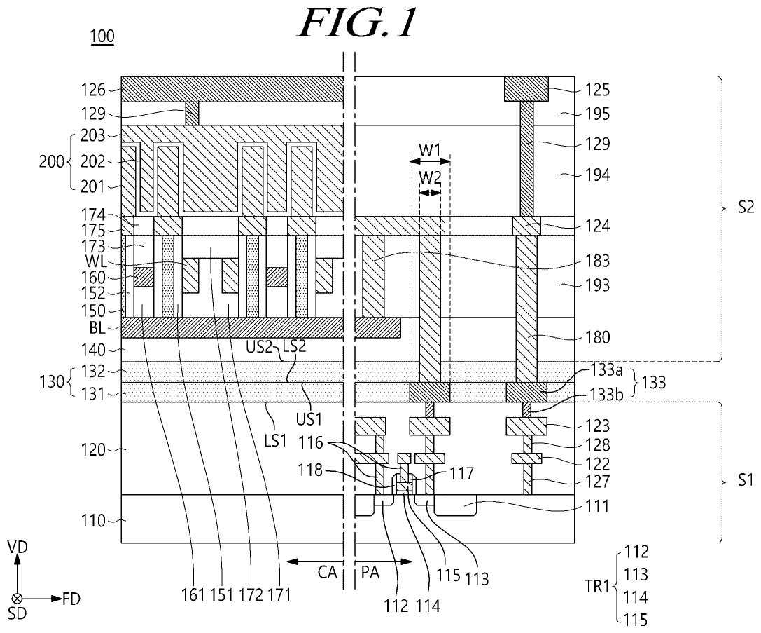

FIG. 1 is a view illustrating a cross-sectional structure of a memory device according to an embodiment of the present disclosure.

Referring to FIG. 1, a memory device 100 includes a first semiconductor structure S1, a second semiconductor structure S2, a bonding insulation layer 130, a pad structure 133, and a contact plug 180.

The first semiconductor structure S1 includes a substrate 110, an element isolation layer 111, a lower transistor TR1, a first gate capping layer 117, a spacer 118, a first insulation layer 120, lines 122 and 123, and contacts 116, 127, and 128.

The second semiconductor structure S2 includes a second insulation layer 140, a bit line BL, an active layer 150, a second gate insulation layer 151, a third gate insulation layer 152, a back gate electrode 160, a second gate capping layer 161, a first insulation pattern 171, a second insulation pattern 172, a third insulation pattern 173, a fourth insulation pattern 174, a word line WL, a landing pad 175, lines 124, 125, and 126, a fourth contact 129, a third insulation layer 193, a fourth insulation layer 194, a fifth insulation layer 195, and a capacitor 200.

The lower transistor TR1 includes a source area 112, a drain area 113, a first gate insulation layer 114, and a gate electrode layer 115. The pad structure 133 includes a first pad 133a and a first pad contact 133b. The capacitor 200 includes a lower electrode 201, a dielectric layer 202, and an upper electrode 203.

The substrate 110 may include a semiconductor substrate such as a silicon wafer or a silicon on insulator (SOI) wafer. The substrate 110 may include a group III-V semiconductor substrate, e.g., a compound semiconductor substrate such as GaAs. The substrate 110 may include monocrystalline silicon, polysilicon, amorphous silicon, monocrystalline silicon germanium, polycrystalline silicon germanium, carbon-doped silicon, or a combination thereof.

The substrate 110 may include a cell area CA and a peripheral area PA. A memory cell is disposed in the cell area CA. The peripheral area PA is disposed around the cell area CA. Various contacts for connecting the peripheral circuit, that supplies various signals and voltages to the memory cell, to the memory cell may be disposed in the peripheral area PA. For example, a contact plug 180 for connecting the bit line BL and the lower transistor TR1 may be disposed in the peripheral area PA.

In the peripheral area PA, at least one element isolation layer 111 is disposed in the substrate 110. The element isolation layer 111 may be formed using a trench element isolation technology such as shallow trench isolation (STI). The element isolation layer 111 may include silicon oxide, silicon nitride, silicon oxynitride, low-K dielectrics, high-K dielectrics, or a combination thereof.

The lower transistor TR1 is disposed on the substrate 110. In an embodiment, the lower transistor TR1 may be one of transistors included in the peripheral circuit. The first contact 116 is connected to the source area 112 and the drain area 113 of the lower transistor TR1 formed in the substrate 110. The second contact 127, the first line 122, the third contact 128, and the second line 123 may be sequentially disposed on the substrate 110 in an area other than the area in which the lower transistor TR1 is disposed. The first line 122 may be connected to the first contact 116 and the second contact 127. The second line 123 may be connected to the third contact 128. The first insulation layer 120 is disposed to cover the lower transistor TR1, the first contact 116, the second contact 127, the first line 122, the third contact 128, and the second line 123.

The second line 123 may be referred to as a lower line. The second line 123 may be connected to the drain area 113 of the lower transistor TR1 through the first contact 116, the first line 122, and the third contact 128.

The pad structure 133 is disposed on the second line 123. The pad structure 133 may be electrically connected to the first semiconductor structure S1. The first pad contact 133b passes through the first insulation layer 120 and is connected to the second line 123. The first pad 133a is disposed on the first pad contact 133b and is connected to the first pad contact 133b. The first pad 133a is disposed in the first bonding insulation layer 131. The first pad 133a may pass through the first bonding insulation layer 131. For example, the upper surface of the first pad 133a may form substantially the same plane as the upper surface US1 of the first bonding insulation layer 131. Further, the lower surface of the first pad 133a may form substantially the same plane as the lower surface LS1 of the first bonding insulation layer 131.

In an embodiment, the width W1 of the upper surface of the pad structure 133 may be greater than the width W2 of the contact plug 180.

In an embodiment, the first pad 133a and the first pad contact 133b may be formed in the same process operation. For example, the first pad 133a may include the same material as the material forming the first pad contact 133b. Alternatively, in another embodiment, the first pad 133a and the first pad contact 133b may be formed in different process operations. For example, the first pad contact 133b may be formed first, and then the first pad 133a may be formed on the first pad contact 133b.

The first bonding insulation layer 131 is disposed on the first semiconductor structure S1. The first bonding insulation layer 131 is disposed between the first semiconductor structure S1 and the second semiconductor structure S2. The second bonding insulation layer 132 is disposed under the second semiconductor structure S2. The second bonding insulation layer 132 is disposed between the first bonding insulation layer 131 and the second semiconductor structure S2. In an embodiment, the upper surface US1 of the first bonding insulation layer 131 and the lower surface LS2 of the second bonding insulation layer 132 may form substantially the same plane.

The first gate insulation layer 114 and the first insulation layer 120 may include silicon oxide, silicon nitride, silicon oxynitride, high-K dielectric, or a combination thereof. The gate electrode 115, the first contact 116, the second contact 127, the first line 122, the third contact 128, the second line 123, and the pad structure 133 may include a conductive material such as metal, metal oxide, metal nitride, metal silicide, polysilicon, conductive carbon, or a combination thereof. The bonding insulation layer 130 may include silicon oxide, silicon nitride, silicon oxynitride, silicon carbonitride, high-K dielectric, or a combination thereof.

Each of the first pad 133a and the first pad contact 133b may include a barrier layer and a conductive layer. The conductive layer may include copper (Cu). The barrier layer may include titanium (Ti), titanium nitride (TiN), tantalum (Ta), tantalum nitride (TaN), or a combination thereof.

A second semiconductor structure S2 is disposed on the second bonding insulation layer 132. The second semiconductor structure S2 may be bonded to the first semiconductor structure S1 through a bonding insulation layer 130. The bonding insulation layer 130 may also be referred to as a bonding structure.

The second insulation layer 140 is disposed on the second bonding insulation layer 132. A bit line BL is disposed on the second insulation layer 140. The bit line BL extends along the first direction FD. For example, the bit line BL may extend from the cell area CA to the peripheral area PA along the first direction FD. The second insulation layer 140 may include silicon oxide, silicon nitride, silicon oxynitride, silicon carbonitride, high-K dielectric, or a combination. The bit line BL may include a conductive material such as metal, metal nitride, metal silicide, polysilicon, conductive carbon, or a combination thereof.

A memory cell is disposed on the bit line BL in the cell area CA. In an embodiment, the memory cell may include one transistor and one capacitor. Hereinafter, an embodiment in which the memory cell includes one transistor and one capacitor is described.

The active layer 150 contacts the bit line BL and extends in a vertical direction. The active layer 150 may include a channel area formed in an area overlapping the word line WL or the back gate electrode 160 in the first direction FD. The active layer 150 may include a source or drain area formed around the channel area. The active layer 150 may include polysilicon or single crystalline silicon.

A second gate insulation layer 151 and a third gate insulation layer 152 are disposed on a side surface of the active layer 150. The second gate insulation layer 151 is disposed between the active layer 150 and the word line WL in the first direction FD. The second gate insulation layer 151 extends in a vertical direction. The third gate insulation layer 152 is disposed between the active layer 150 and the back gate electrode 160 in the first direction FD. The third gate insulation layer 152 extends in a vertical direction. The second gate insulation layer 151 and the third gate insulation layer 152 may include silicon oxide, silicon nitride, silicon oxynitride, silicon carbonitride, a high-K dielectric, or a combination thereof.

The word line WL, the first insulation pattern 171, and the second insulation pattern 172 are disposed between the second gate insulation layers 151 facing each other. The length of the word line WL in the vertical direction may be less than the length of the active layer 150 in the vertical direction. The first insulation pattern 171 is positioned between the word lines WL facing each other. The first insulation pattern 171 may cover one side surface and a lower surface of the word line WL. The second insulation pattern 172 may cover an upper surface of the first insulation pattern 171 and the word line WL.

The back gate electrode 160, the second gate capping layer 161, and the third insulation pattern 173 are disposed between the third gate insulation layers 152 facing each other. The length of the back gate electrode 160 in the vertical direction may be less than the length of the active layer 150 in the vertical direction. The second gate capping layer 161 is disposed between the back gate electrode 160 and the bit line BL. The third insulation pattern 173 is disposed on the back gate electrode 160. The second gate capping layer 161, the back gate electrode 160, and the third insulation pattern 173 overlap each other in the vertical direction.

The word line WL and the back gate electrode 160 may include a conductive material such as metal, metal nitride, metal silicide, polysilicon, conductive carbon, or a combination thereof. The first insulation pattern 171, the second insulation pattern 172, the third insulation pattern 173, the fourth insulation pattern 174, and the second gate capping layer 161 may include silicon oxide, silicon nitride, silicon oxynitride, silicon carbonitride, high-K dielectric, or a combination thereof.

A fourth insulation pattern 174 and a landing pad 175 are disposed on the active layer 150, the second and third gate insulation layers 151 and 152, the second insulation pattern 172, and the third insulation pattern 173. The landing pad 175 corresponds to one active layer 150. The landing pad 175 contacts the upper surface of the corresponding active layer 150. The fourth insulation pattern 174 is disposed between the landing pads 175. The landing pad 175 may include a conductive material such as metal, metal nitride, metal silicide, polysilicon, conductive carbon, or a combination thereof. The fourth insulation pattern 174 may include silicon oxide, silicon nitride, silicon oxynitride, silicon carbonitride, high-K dielectric, or a combination thereof.

A bit line connection contact 183 is disposed on the bit line BL in the peripheral area PA. The third line 124 and the fourth insulation pattern 174 may be disposed on the bit line connection contact 183. The third line 124 may be referred to as an upper line. One side of the bit line connection contact 183 contacts the upper surface of the bit line BL. The other side of the bit line connection contact 183 contacts the third line 124.

The contact plug 180 is disposed on the pad structure 133. One side of the contact plug 180 is connected to the first pad 133a. The other side of the contact plug 180 is connected to the third line 124. The contact plug 180 extends in a vertical direction from the upper surface of the first pad 133a, passes through the second bonding insulation layer 132, the second insulation layer 140 and the third insulation layer 193, and contacts the lower surface of the third line 124.

The bit line BL may be connected to the second line 123 through the bit line connection contact 183, the third line 124, the contact plug 180, and the pad structure 133. The second line 123 may be connected to the lower transistor TR1 through the third contact 128, the first line 122, and the first contact 116.

The bit line connection contact 183, the third line 124, and the contact plug 180 may include a conductive material such as metal, metal oxide, metal nitride, metal silicide, polysilicon, conductive carbon, or a combination thereof.

The capacitor 200 is disposed on the fourth insulation pattern 174 and the landing pad 175 in the cell area CA. The lower electrode 201 of the capacitor 200 may correspond to one landing pad 175. The lower electrode 201 contacts the upper surface of the landing pad 175. The dielectric layer 202 is disposed to cover the side surface and the upper surface of the lower electrode 201, and the upper surface of the fourth insulation pattern 174. In an embodiment, the dielectric layer 202 may conformally cover the side surface and the upper surface of the lower electrode 201. The upper electrode 203 is disposed on the dielectric layer 202. The lower electrode 201 and the upper electrode 203 may include a conductive material such as metal, metal oxide, metal nitride, metal silicide, polysilicon, conductive carbon, or a combination thereof. The dielectric layer 202 may include a high dielectric material, silicon oxide, silicon nitride, or a combination thereof.

A fourth contact 129 and a fifth insulation layer 195 are disposed on the upper electrode 203. A fifth line 126 is disposed on the fourth contact 129.

The fourth insulation layer 194 and the fourth contact 129 are disposed on the third line 124 and the fourth insulation pattern 174 in the peripheral area PA. The fourth contact 129 may pass through the fourth insulation layer 194 to contact the upper surface of at least one third line 124. The fifth insulation layer 195 is disposed on the fourth insulation layer 194. The fifth line 125 is disposed in the fifth insulation layer 195.

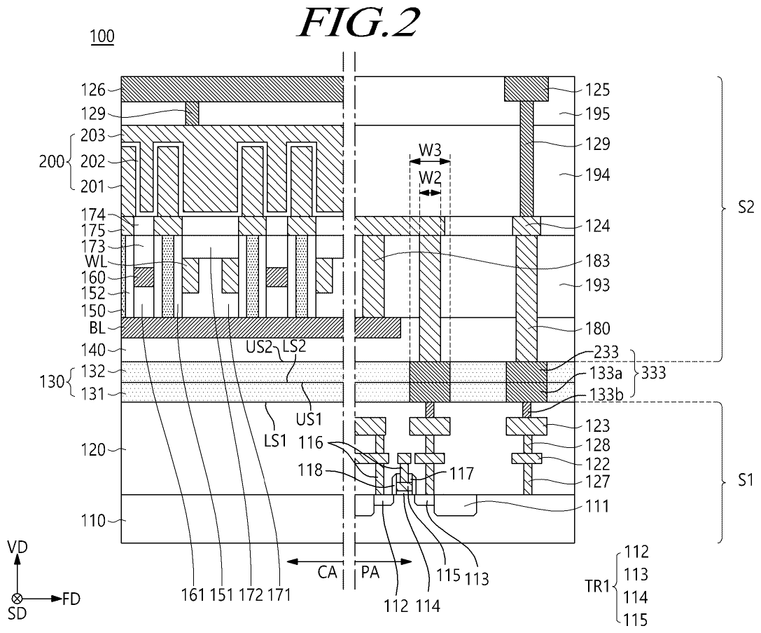

FIG. 2 is a view illustrating another cross-sectional structure of a memory device according to an embodiment of the present disclosure.

Referring to FIG. 2, a first semiconductor structure S1 of a memory device 100 according to an embodiment of the present disclosure includes a substrate 110, an element isolation layer 111, a lower transistor TR1, a first gate capping layer 117, a first insulation layer 120, lines 122 and 123, and contacts 116, 127, and 128.

The second semiconductor structure S2 includes a second pad 233, a second insulation layer 140, a bit line BL, an active layer 150, a second gate insulation layer 151, a third gate insulation layer 152, a back gate electrode 160, a second gate capping layer 161, a first insulation pattern 171, a second insulation pattern 172, a third insulation pattern 173, a fourth insulation pattern 174, a word line WL, a landing pad 175, lines 124, 125, and 126, a fourth contact 129, a third insulation layer 193, a fourth insulation layer 194, a fifth insulation layer 195, and a capacitor 200.

The pad structure 333 includes a first pad 133a, a first pad contact 133b, and a second pad 233. The first pad contact 133b is connected to the second line 123. The first pad 133a is connected to the first pad contact 133b. The first pad 133a may pass through the first bonding insulation layer 131. For example, the upper surface of the first pad 133a may form substantially the same plane as the upper surface US1 of the first bonding insulation layer 131 and the lower surface of the first pad 133a may form substantially the same plane as the lower surface LS1 of the first bonding insulation layer 131. The pad structure 333 may be electrically connected to the first semiconductor structure S1.

The second pad 233 is disposed on the first pad 133a. The lower surface of the second pad 233 contacts the upper surface of the first pad 133a. The second pad 233 is disposed in the second bonding insulation layer 132. The second pad 233 may pass through the second bonding insulation layer 132. For example, the upper surface of the second pad 233 may form substantially the same plane as the upper surface US2 of the second bonding insulation layer 132 and the lower surface of the second pad 233 may form substantially the same plane as the lower surface LS2 of the second bonding insulation layer 132.

In an embodiment, the width W3 of the upper surface of the second pad 233 may be greater than the width W2 of the contact plug 180. The width W1 of the upper surface of the pad structure 333 described with reference to FIG. 1 may be substantially the same as the width W3 of the upper surface of the pad structure 333 of FIG. 2.

In an embodiment, the first pad 133a and the first pad contact 133b may be formed simultaneously in the same process operation. For example, the first pad 133a may include the same material as the material forming the first pad contact 133b. Alternatively, in another embodiment, the first pad 133a and the first pad contact 133b may be formed in different process operations. For example, the first pad contact 133b may be formed first, and then the first pad 133a may be formed on the first pad contact 133b.

In an embodiment, each of the first pad 133a and the first pad contact 133b may include a barrier layer and a conductive layer. The conductive layer may include copper (Cu). The barrier layer may include titanium (Ti), titanium nitride (TiN), tantalum (Ta), tantalum nitride (TaN), or a combination thereof.

The second pad 233 may include the same material as the material forming the first pad 133a. In an embodiment, the second pad 233 may include copper.

In an embodiment, the second pad 233 may include a barrier layer and a conductive layer. The conductive layer may include copper. The barrier layer may include titanium (Ti), titanium nitride (TiN), tantalum (Ta), tantalum nitride (TaN), or a combination thereof. The barrier layer may be disposed on a lower surface of the conductive layer.

The contact plug 180 is disposed on the second pad 233. One side of the contact plug 180 contacts the upper surface of the second pad 233. The other side of the contact plug 180 contacts the lower surface of the third line 124. The contact plug 180 may extend in a vertical direction from the upper surface of the second pad 233, pass through the second insulation layer 140 and the third insulation layer 193, and may contact the lower surface of the third line 124.

The bit line BL may be connected to the second line 123 through the bit line connection contact 183, the third line 124, the contact plug 180, the second pad 233, and the pad structure 333. The second line 123 may be connected to the lower transistor TR1 through the third contact 128, the first line 122, and the first contact 116.

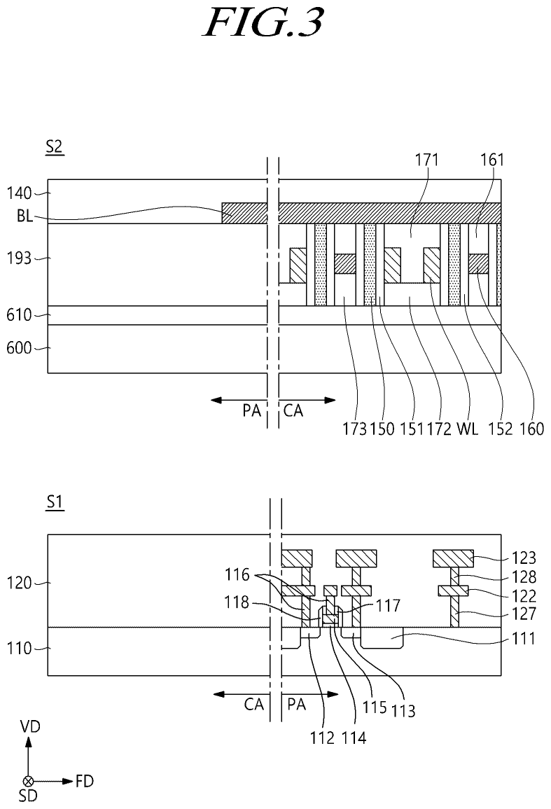

FIGS. 3 to 13 are views illustrating a method for manufacturing a memory device according to embodiments of the present disclosure.

Referring to FIG. 3, a first semiconductor structure S1 and a second semiconductor structure S2 are prepared. The first semiconductor structure S1 and the second semiconductor structure S2 may be different wafers.

The second semiconductor structure S2 includes a first substrate 600, a sixth insulation layer 610 formed on the first substrate 600, a third insulation layer 193, an active layer 150, a second gate insulation layer 151, a third gate insulation layer 152, a word line WL, a back gate electrode 160, a second gate capping layer 161, a first insulation pattern 171, a second insulation pattern 172, and a third insulation pattern 173 formed on the sixth insulation layer 610, and a bit line BL and a second insulation layer 140 formed on the third insulation layer 193.

The first semiconductor structure S1 includes a substrate 110, an element isolation layer 111 formed in the substrate 110, and a lower transistor TR1, a second contact 127, a first line 122, a third contact 128, a second line 123, and a first insulation layer 120 formed on the substrate 110. The first insulation layer 120 may include multiple layers.

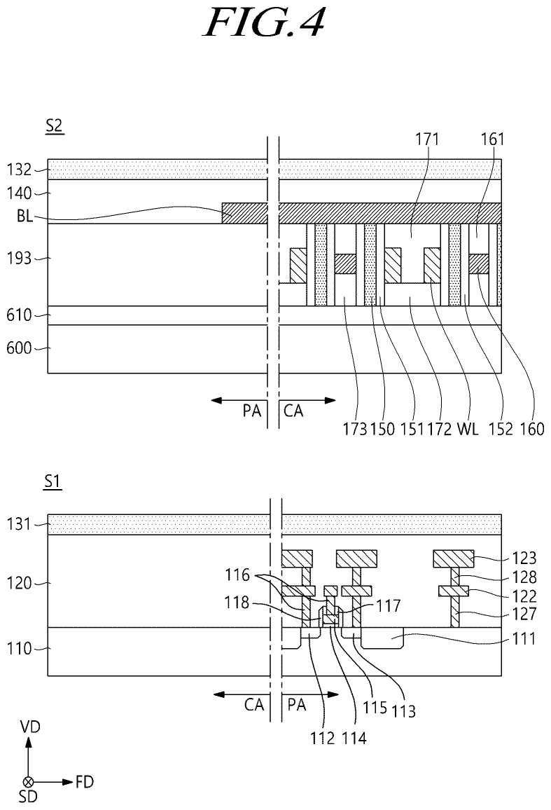

Referring to FIG. 4, a second bonding insulation layer 132 may be formed on the second insulation layer 140 of the second semiconductor structure S2. A first bonding insulation layer 131 may be formed on the first insulation layer 120 of the first semiconductor structure S1. The first bonding insulation layer 131 may include the same material as the material forming the second bonding insulation layer 132. In an embodiment, the first bonding insulation layer 131 and the second bonding insulation layer 132 may include, for example, silicon carbonitride.

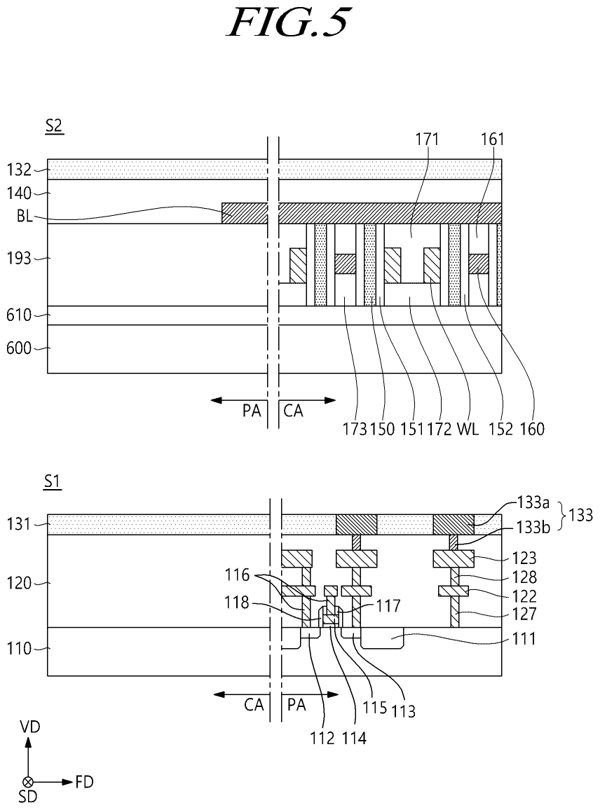

Referring to FIG. 5, a pad structure 133 passing through the first bonding insulation layer 131 and extending into the first insulation layer 120 may be formed. The pad structure 133 may pass through the first bonding insulation layer 131 to be electrically connected to the first semiconductor structure S1. The process of forming the pad structure 133 may include a process of etching the first bonding insulation layer 131 and the first insulation layer 120.

The pad structure 133 includes a first pad contact 133b connected to the second line 123 and a first pad 133a connected to the first pad contact 133b on the first pad contact 133b. In an embodiment, the first pad 133a and the first pad contact 133b may be formed in the same process operation. For example, after the first bonding insulation layer 131 and the first insulation layer 120 are etched, the first pad 133a and the first pad contact 133b may be formed simultaneously by filling the etched area with a conductive material. Alternatively, in another embodiment, the first pad 133a and the first pad contact 133b may be formed in different process operations. For example, the space in which the first pad contact 133b is to be formed may be first etched, and the etched area may be filled with a conductive material, forming the first pad contact 133b. Thereafter, the space in which the first pad 133a is to be formed may be etched, and the etched area may be filled with a conductive material to form the first pad 133a.

The upper surface of the pad structure 133 may form substantially the same plane as the upper surface US1 of the first bonding insulation layer 131.

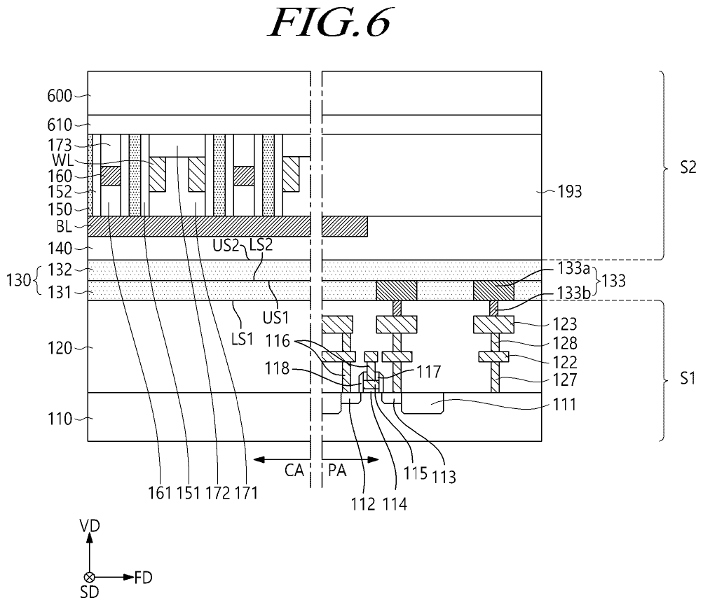

Referring to FIG. 6, the second semiconductor structure S2 is bonded on the first semiconductor structure S1. In an embodiment, the process of bonding the first semiconductor structure S1 and the second semiconductor structure S2 may include a process of applying heat after bringing the second bonding insulation layer 132 in contact with the upper surface US1 of the first bonding insulation layer 131. The upper surface of the pad structure 133 may contact the lower surface LS2 of the second bonding insulation layer 132.

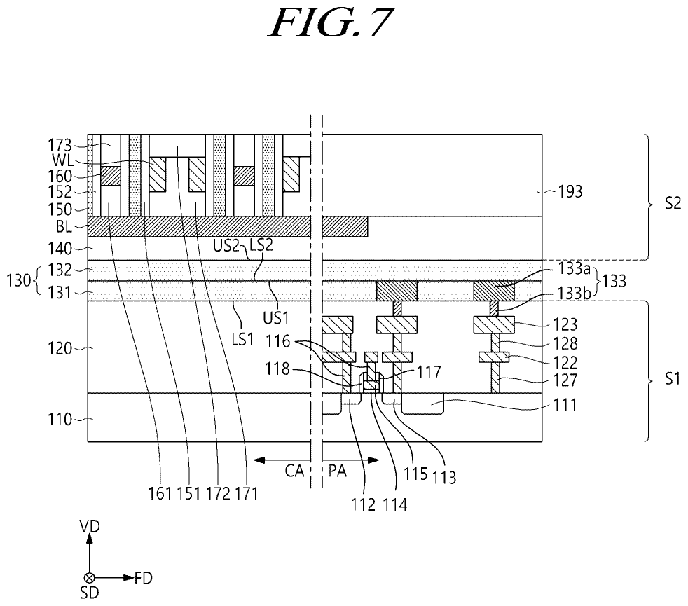

Referring to FIG. 7, the first substrate 600 and the sixth insulation layer 610 may be removed. In an embodiment, the first substrate 600 may be removed through a grinding process or a chemical mechanical polishing (CMP) process. In an embodiment, the sixth insulation layer 610 may be removed by a wet etching process.

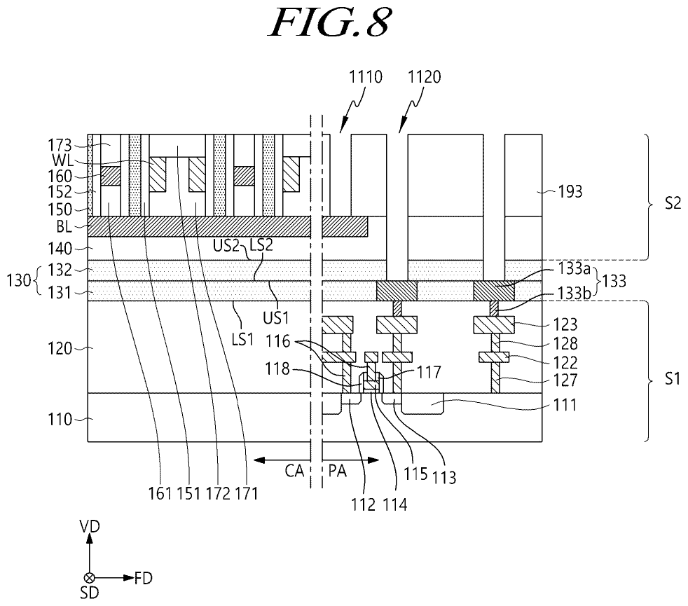

Referring to FIG. 8, a first through hole 1110 and a second through hole 1120 are formed in the peripheral area PA. The first through hole 1110 may pass through the third insulation layer 193 in the vertical direction to expose an upper surface of the bit line BL. The second through hole 1120 may pass through the third insulation layer 193, the second insulation layer 140, and the second bonding insulation layer 132 in the vertical direction to expose the upper surface of the pad structure 133, e.g., the upper surface of the first pad 133a. The process of forming the first through hole 1110 and the second through hole 1120 may include an anisotropic etching process. In an embodiment, forming the first through hole 1110 and the second through hole 1120 may be performed in the same process operation.

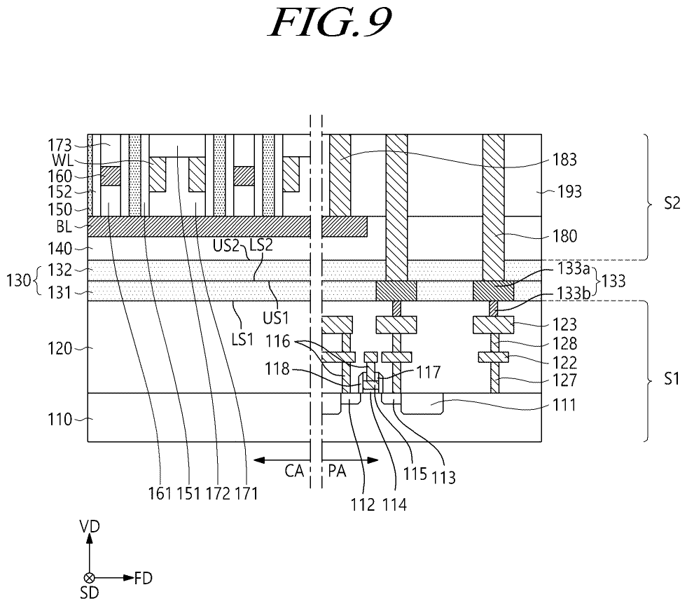

Referring to FIG. 9, the bit line connection contact 183 and the contact plug 180 are formed by filling the first through hole 1110 and the second through hole 1120, respectively, with a conductive material. The lower surface of the bit line connection contact 183 may contact the upper surface of the bit line BL. The lower surface of the contact plug 180 may contact the upper surface of the pad structure 133. The bit line connection contact 183 may include the same material as the material forming the contact plug 180.

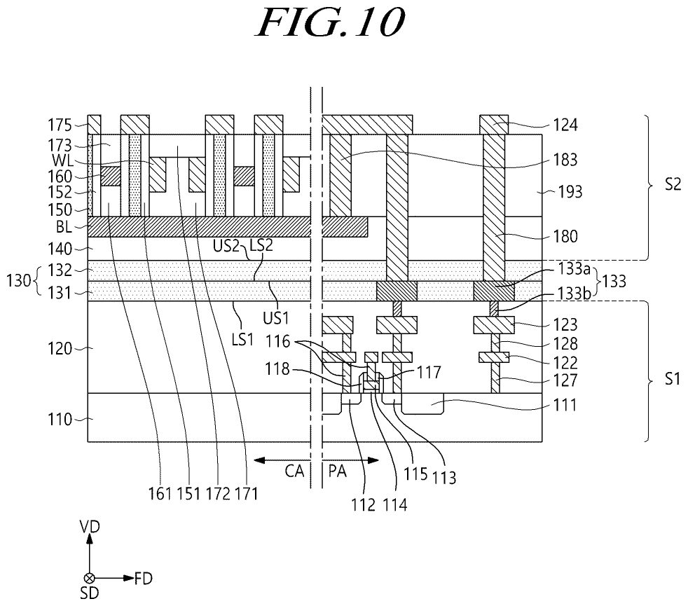

Referring to FIG. 10, a landing pad 175 may be formed on the corresponding active layer 150 in the cell area CA. The lower surface of the landing pad 175 contacts the upper surface of the corresponding active layer 150. In the peripheral area PA, the third line 124 may be formed on the bit line connection contact 183 and the contact plug 180. At least one third line 124 may connect the bit line connection contact 183 and the contact plug 180. The bit line BL may be connected to the pad structure 133 through the bit line connection contact 183, at least one third line 124 connected to the bit line connection contact 183, and the contact plug 180 connected to the at least one third line 124.

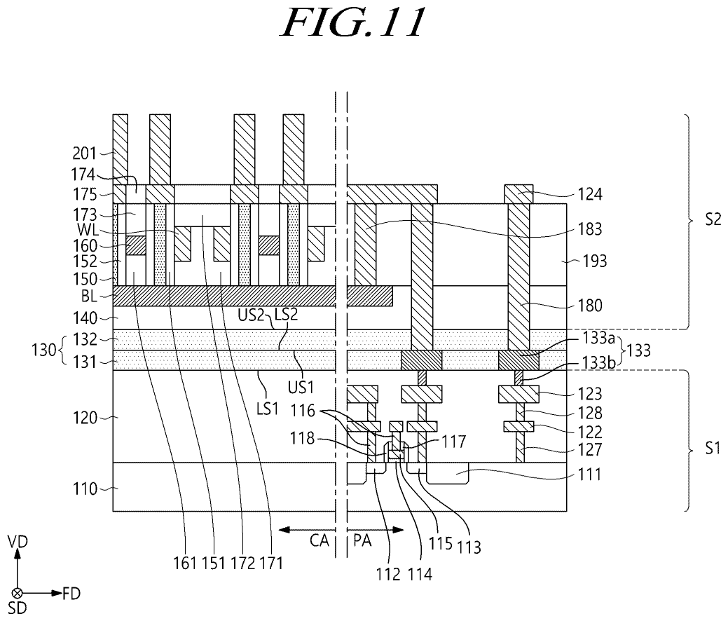

Referring to FIG. 11, a fourth insulation pattern 174 covering the landing pad 175 and the third line 124 is formed. The fourth insulation pattern 174 may be positioned between the landing pads 175 and between the third lines 124.

After the fourth insulation pattern 174 is formed, the lower electrode 201 may be formed on the landing pad 175 in the cell area CA. The lower electrode 201 may be formed on the upper surface of one corresponding landing pad 175. The lower surface of the lower electrode 201 contacts the upper surface of the landing pad 175.

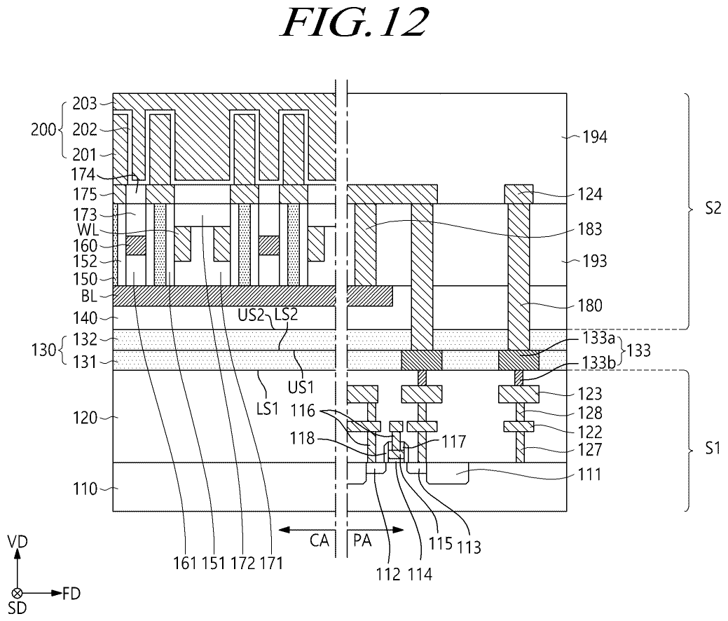

Referring to FIG. 12, a dielectric layer 202 may be formed on the lower electrode 201 and the fourth insulation pattern 174 in the cell area CA. In an embodiment, the dielectric layer 202 may be conformally formed on the side surface and the upper surface of the lower electrode 201. The dielectric layer 202 covers the side surface and the upper surface of the lower electrode 201, and the upper surface of the fourth insulation pattern 174. The upper electrode 203 may be formed on the dielectric layer 202. The dielectric layer 202 and the upper electrode 203 may not be disposed in the peripheral area PA. The fourth insulation layer 194 is formed in the peripheral area PA.

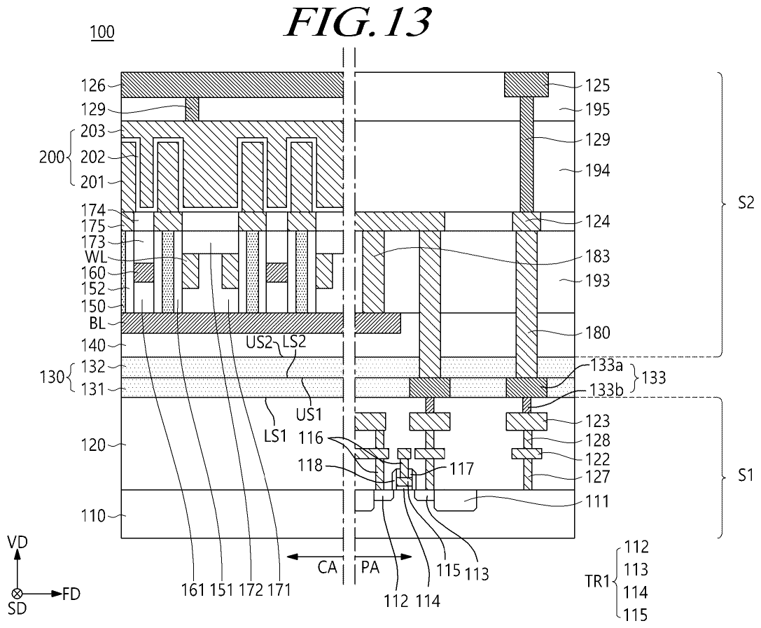

Referring to FIG. 13, a fifth insulation layer 195 may be formed on the upper electrode 203 and the fourth insulation layer 194. After the fifth insulation layer 195 is formed, a fourth contact 129 passing through the fifth insulation layer 195 is formed. In the cell area CA, the fourth contact 129 contacts the upper surface of the upper electrode 203. In the peripheral area PA, the fourth contact 129 contacts the upper surface of the third line 124.

A fifth line 126 may be formed on the fourth contact 129 in the cell area CA. A fourth line 125 may be formed on the fourth contact 129 in the peripheral area PA. The fourth line 125 and the fifth line 126 each may be formed in the fifth insulation layer 195.

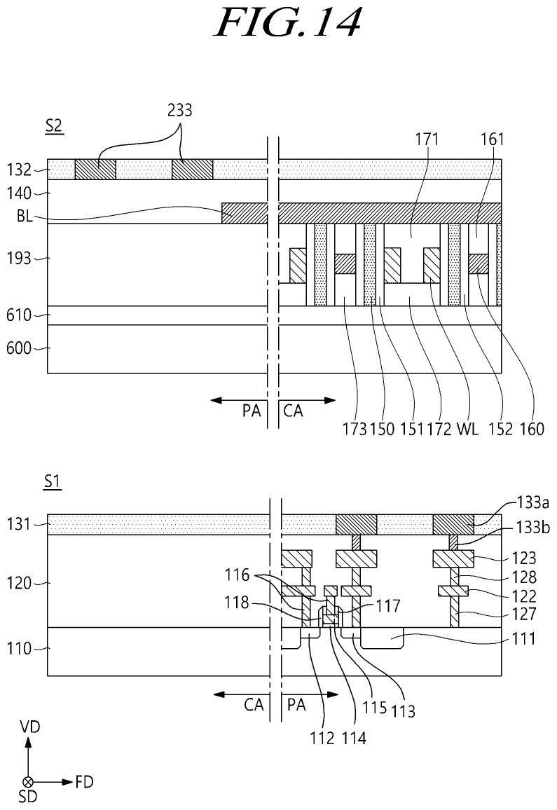

FIGS. 14 to 16 are views illustrating another method for manufacturing a memory device according to embodiments of the present disclosure.

The first semiconductor structure S1 and the second semiconductor structure S2 illustrated in FIG. 14 may be formed by the same method as the method for manufacturing the memory device described with reference to FIGS. 3 to 5. For example, the first pad 133a and the first pad contact 133b may be formed by the same method as the method for forming the first pad 133a and the first pad contact 133b described with reference to FIG. 5.

Referring to FIG. 14, a second pad 233 passing through the second bonding insulation layer 132 may be formed. The process of forming the second pad 233 may include etching the second bonding insulation layer 132. The upper surface of the second pad 233 may form substantially the same plane as the upper surface US2 of the second bonding insulation layer 132.

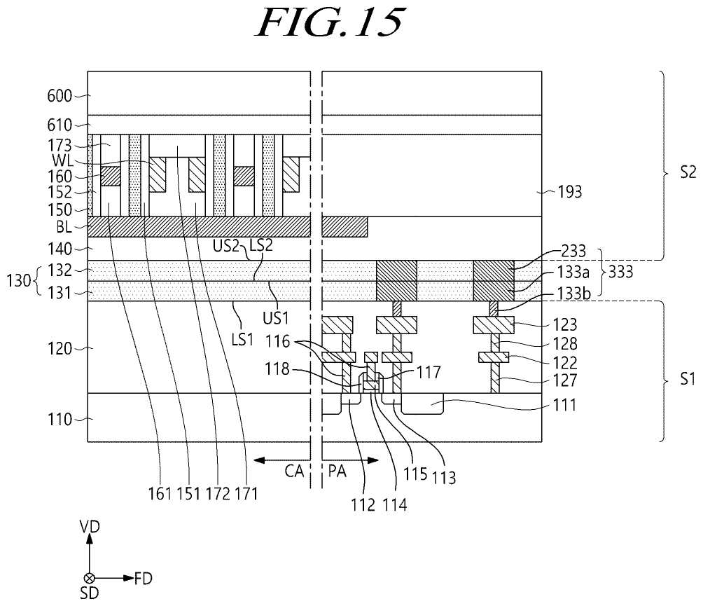

Referring to FIG. 15, the second semiconductor structure S2 is bonded on the first semiconductor structure S1. In an embodiment, bonding the first semiconductor structure S1 with the second semiconductor structure S2 may include applying heat after bringing the second bonding insulation layer 132 in contact with the upper surface US1 of the first bonding insulation layer 131.

The upper surface of the first pad 133a may contact the lower surface of the second pad 233. The upper surface US1 of the first bonding insulation layer 131 may contact the lower surface LS2 of the second bonding insulation layer 132. As the second pad 233 is formed to overlap with the first pad 133a, the lower surface LS2 of the second bonding insulation layer 132 may contact only the first bonding insulation layer 131, thereby implementing bonding between the insulation layers.

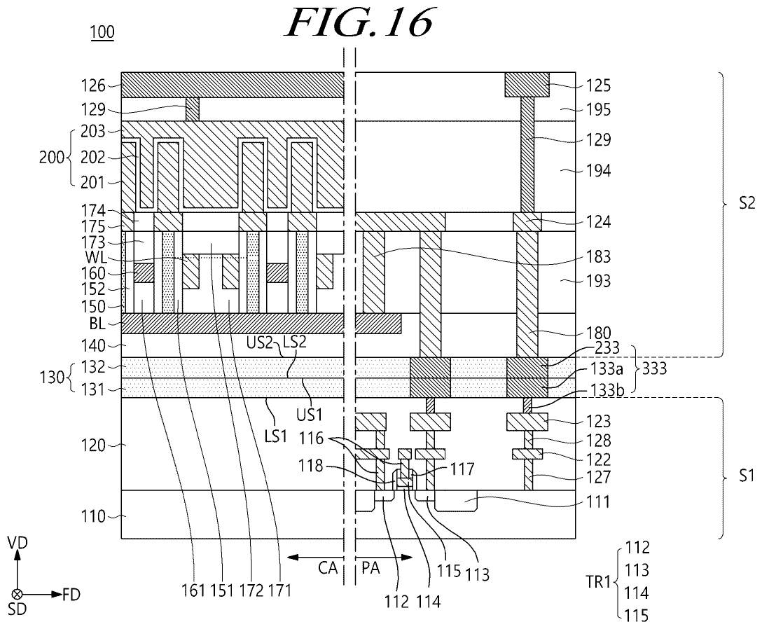

Referring to FIG. 16, a contact plug 180 may be formed on the second pad 233. The lower surface of the contact plug 180 may contact the upper surface of the second pad 233. The contact plug 180 may be formed by substantially the same method as the method for manufacturing the contact plug 180 described with reference to FIGS. 7 to 9.

The third line 124, the landing pad 175, the fourth insulation pattern 174, the capacitor 200, the fourth insulation layer 194, the fourth contact 129, the fifth insulation layer 195, the fourth line 125, and the fifth line 126 may be formed by the same method as the method for manufacturing the memory device described with reference to FIGS. 10 to 13.

Referring back to FIG. 1, the pad structure 133 is disposed in the first bonding insulation layer 131. The contact plug 180 passes through the third insulation layer 193, the second insulation layer 140, and the second bonding insulation layer 132 to contact the upper surface of the pad structure 133.

According to embodiments of the present disclosure, as the pad structure 133 is disposed on the second line 123, a process failure that may occur due to misalignment with the bit line BL when the bit line connection contact 183 is formed may be prevented. This is described below in detail. The bit line connection contact 183 and the contact plug 180 may be formed in the same process operation. In this case, the through hole for forming the bit line connection contact 183 and the through hole for forming the contact plug 180 are formed at different depths, and the greater the depth difference between the through holes, the more likely it is to cause errors in landing alignment. Moreover, since the width of the bit line BL is very small, errors occurring in the landing alignment process mainly occur in the area where the bit line connection contact 183 lands on the bit line BL. According to embodiments of the present disclosure, since the pad structure 133 is disposed to reduce the depth difference between the through holes for forming the contact plug 180 and the bit line connection contact 183, errors occurring in the landing alignment process may be reduced. Accordingly, a failure of electrical connection between the memory cell and the peripheral circuit may be prevented.

The above-described embodiments are merely examples, and it will be appreciated by one of ordinary skill in the art that various changes may be made thereto without departing from the scope of the present disclosure. Accordingly, the embodiments set forth herein are provided for illustrative purposes, but not to limit the scope of the present disclosure, and should be appreciated that the scope of the present disclosure is not limited by the embodiments. Furthermore, the embodiments may be combined to form additional embodiments.

What is claimed is:

1. A memory device comprising:
a first semiconductor structure;
a second semiconductor structure disposed on the first semiconductor structure;
a first bonding insulation layer disposed between the first semiconductor structure and the second semiconductor structure;
a second bonding insulation layer disposed between the first bonding insulation layer and the second semiconductor structure;
a pad structure connected to the first semiconductor structure through the first bonding insulation layer; and
a contact plug connected to the pad structure, the contact plug extending in a direction perpendicular to an upper surface of the pad structure to be connected to the second semiconductor structure, and having a width less than a width of the upper surface of the pad structure.

2. The memory device of claim 1, wherein the upper surface of the pad structure forms substantially the same plane as an upper surface of the first bonding insulation layer.

3. The memory device of claim 1, wherein the pad structure includes a first pad disposed in the first bonding insulation layer and a first pad contact disposed under the first pad.

4. The memory device of claim 1, wherein the contact plug contacts the upper surface of the pad structure through the second bonding insulation layer.

5. The memory device of claim 1, wherein the pad structure includes a first pad disposed in the first bonding insulation layer, a first pad contact disposed under the first pad, and a second pad disposed on the first pad.

6. The memory device of claim 5, wherein a width of an upper surface of the second pad is greater than a width of the contact plug.

7. The memory device of claim 5, wherein the second pad is disposed in the second bonding insulation layer.

8. The memory device of claim 5, wherein the contact plug contacts an upper surface of the second pad.

9. The memory device of claim 1, wherein the first semiconductor structure includes:
a lower transistor; and
a lower line connected to a source area or a drain area of the lower transistor, wherein the second semiconductor structure includes:
a bit line;
a bit line connection contact having a side connected to an upper surface of the bit line; and
an upper line connected to another side of the bit line connection contact, and
wherein the pad structure is connected to the lower line, and the contact plug is connected to the upper line.

10. A memory device comprising:
a substrate including a cell area and a peripheral area;
a bonding insulation layer on the substrate;
a pad structure disposed in the peripheral area and extending to an inside of the bonding insulation layer; and
a contact plug connected to the pad structure, extending in a direction perpendicular to an upper surface of the pad structure, and having a width less than a width of the upper surface of the pad structure.

11. The memory device of claim 10, wherein the bonding insulation layer includes a first bonding insulation layer and a second bonding insulation layer on the first bonding insulation layer, and
wherein the upper surface of the pad structure forms substantially the same plane as an upper surface of the first bonding insulation layer.

12. The memory device of claim 10, wherein the pad structure includes a first pad disposed in the bonding insulation layer and a first pad contact disposed under the first pad.

13. The memory device of claim 10, wherein the contact plug contacts the upper surface of the pad structure through the bonding insulation layer.

14. The memory device of claim 10, wherein the pad structure includes a first pad disposed in the bonding insulation layer, a first pad contact disposed under the first pad, and a second pad disposed on the first pad.

15. The memory device of claim 14, wherein a width of an upper surface of the second pad is greater than a width of the contact plug.

16. The memory device of claim 14, wherein an upper surface of the second pad forms substantially the same plane as an upper surface of the bonding insulation layer.

17. The memory device of claim 14, wherein the contact plug contacts an upper surface of the second pad.

18. The memory device of claim 10, further comprising:
a lower transistor disposed on the substrate;
a lower line connected to a source area or a drain area of the lower transistor;
a bit line on the bonding insulation layer;
a bit line connection contact having a side connected to an upper surface of the bit line; and
an upper line connected to another side of the bit line connection contact,
wherein the contact plug is connected to the upper line, and the pad structure is connected to the lower line.

19. A memory device comprising:
a first semiconductor structure; and a second semiconductor structure bonded together with the first semiconductor structure via a bonding structure;
a pad structure connected to the first semiconductor structure through the bonding structure; and
a contact plug connected to the pad structure, the contact plug extending in a direction perpendicular to an upper surface of the pad structure to connect to the bonding structure.
